(19) United States
(12) Patent Application Publication
(10) Pub. No.: US 2026/0118429 A1
(43) Pub. Date: Apr. 30, 2026

(54) SWITCHGEAR FAULT DIAGNOSIS METHOD AND APPARATUS BASED ON DEEP LEARNING

(71) Applicant: NANKAI UNIVERSITY, TIANJIN (CN)

(72) Inventors: CHUNYAN ZHANG, TIANJIN (CN); JIANLEI ZHANG, TIANJIN (CN); XICHAO TANG, TIANJIN (CN)

(73) Assignee: NANKAI UNIVERSITY, TIANJIN (CN)

(21) Appl. No.: 19/361,082

(22) Filed: Oct. 17, 2025

(30) Foreign Application Priority Data
Oct. 26, 2024 (CN) 2024115073193

(51) Int. Cl. G01R 31/327; G06T 7/00

(52) U.S. Cl. CPC G01R 31/3275; G01R 31/3274; G06T 7/0008; G06T 2207/20084

(57) ABSTRACT

A switchgear fault diagnosis method based on deep learning includes: acquiring partial discharge (PD) data; preprocessing the acquired PD data, and the preprocessing including: performing global statistical feature extraction on the PD data to obtain global statistical features; and converting the PD data into grayscale images; processing the grayscale images using a residual network (ResNet) model integrated with a convolutional block attention module (CBAM) to extract key latent features as key local discriminative features; concatenating the global statistical features and the key local discriminative features to obtain multi-scale features; and classifying the multi-scale features using a multilayer perceptron (MLP) to obtain a switchgear fault diagnosis result. The method analyzes signal features by multi-scale feature fusion from different levels and scales, thereby improving the accuracy and adaptability of fault diagnosis.

### CROSS-REFERENCE TO RELATED APPLICATION

This application claims priority to Chinese Patent Application No. 202411507319.3, filed on Oct. 26, 2024, which is herein incorporated by reference in its entirety.

### TECHNICAL FIELD

The disclosure relates to the field of power equipment technologies, and more particularly to a switchgear fault diagnosis method and apparatus based on deep learning.

### BACKGROUND

During the power generation, transmission, distribution, and conversion processes in power systems, a switchgear is primarily responsible for switching, controlling, and protecting electrical equipment, directly influencing the safety and stability of high-voltage transmission. during the lifecycle of the switchgear—from manufacturing and transportation to assembly, operation, and aging—minor physical defects are inevitably produced. These defects can readily lead to distortion in the electric field strength within the switchgear, resulting in partial discharge (PD) phenomena. As the discharge activity progressively worsens, it can severely affect the stability of power transmission and may even lead to large-scale power supply interruptions.

Li Zhaoshu et al. designed an online monitoring system for PD in a high-voltage switchgear based on a pulse current method to monitor the operational status of the switchgear and determine whether it is in a fault state. This system collects ultra-high-frequency (UHF) signals from the high-voltage switchgear via UHF sensor modules and performs signal denoising using a second-generation wavelet denoising technique. Concurrently, it utilizes an optimal binary tree complex wavelet decomposition method to extract features from the discharge signals, ultimately constructing a PD feature fusion recognition model based on neural network and evidence theory.

Jia Kunqi et al. collected ultrasonic signals from a high-voltage switchgear, extracted waveform feature vectors, first and second correlation coefficients, and peak values of various signal segments to determine PD feature vectors. Subsequently, they combined the UHF detection method with these feature vectors for multi-information fusion, thereby achieving the diagnosis of PD fault types in the high-voltage switchgear.

These algorithms involve complex feature extraction processes and rely on relevant domain knowledge, and usually need the guidance of experts to achieve accurate pattern recognition, indicating a significant dependence on experience and technical expertise. Furthermore, relying solely on manual feature extraction does not enable models to fully comprehend and utilize the features of raw data. When partial discharge patterns are similar, it is difficult to achieve satisfactory fault diagnosis performance.

### SUMMARY

The disclosure aims to solve at least one of the technical problems mentioned above in the related art.

The disclosure provides a switchgear fault diagnosis method and apparatus based on deep learning. By means of multi-scale feature fusion, signal features can be analyzed at different levels and scales, thereby improving fault-diagnosis accuracy and adaptability.

To solve the aforesaid technical problems, the disclosure is implemented as follows.

An embodiment of the disclosure provides a switchgear fault diagnosis method based on deep learning, and the switchgear fault diagnosis method includes S1 to S5:
S1, acquiring PD data;
S2, preprocessing the acquired PD data; where the preprocessing includes performing global statistical feature extraction on the PD data to obtain global statistical features, and performing data type conversion on the PD data to obtain grayscale images;
S3, processing the grayscale images using a residual network (ResNet) model integrated with a convolutional block attention module (CBAM) to extract key latent features as key local discriminative features;
S4, concatenating the global statistical features and the key local discriminative features to obtain multi-scale features; and
S5, classifying the multi-scale features using a multilayer perceptron (MLP) classifier to obtain a switchgear fault diagnosis result.

In some embodiments, in response to the switchgear fault diagnosis result of internal discharge, a processor outputs alarm information to a display, thereby issuing an early warning, and the processor outputs a power-off instruction to the switchgear to power off the switchgear. In some embodiments, in response to the switchgear fault diagnosis result of surface discharge, a processor activates a dehumidification device to make the dehumidification device start a dehumidification function, and the processor outputs prompt information to a display to prompt maintenance personnel to repair the switchgear. In some embodiments, in response to the switchgear fault diagnosis result of corona discharge, a processor outputs a fault report including the fault position and maintenance suggestions to a display to help the maintenance personnel maintain the switchgear.

Additionally, the switchgear fault-diagnosis method based on deep learning according to the disclosure may further include the following technical features.

In some embodiments, the global statistical features include a number of pulses (also referred to as a pulse count), a mean absolute amplitude of the pulses, a standard deviation of the pulses, and maximum and minimum values of the pulses.

In some embodiments, the PD data includes phase resolved pulse sequence (PRPS) data or phase resolved partial discharge (PRPD) data.

In some embodiments, the CBAM includes a channel attention mechanism and a spatial attention mechanism, and a mutual combination of the channel attention mechanism and the spatial attention mechanism effectively extracts the key latent features related to PD patterns.

In some embodiments, the MLP classifier is a multilayer perceptron designed based on the multi-scale features, and the switchgear fault diagnosis result determined thereby includes presence or absence of a fault and a type of the fault.

In some embodiments, the performing data type conversion on the PD data to obtain grayscale images in S2 includes: arranging the PD data into a two-dimensional data matrix, performing normalization on the two-dimensional data matrix to obtain normalized data, multiplying the normalized data by 255 to obtain multiplied data, and converting the multiplied data into an integer format to adapt to a pixel value range of the grayscale images from 0 to 255, thereby obtaining the grayscale images that clearly display spatial distribution and intensity of partial discharge activity.

In some embodiments, the CBAM is embedded within a basic block of the ResNet model.

In some embodiments, the channel attention mechanism includes an average pool layer and a max pool layer arranged in parallel, followed by two fully-connected layers with a ReLU module in between;
the channel attention mechanism is expressed as:

$${M}_{c} ( F ) = σ ( MLP ( AvgPool ( F ) ) + MLP ( MaxPool ( F ) ) ) = σ ( {W}_{1} ( {W}_{0} ( {F}_{avg}^{c} ) ) + {W}_{1} ( {W}_{0} ( {F}_{max}^{c} ) ) )$$

where F represents an input feature map, σ represents a sigmoid activation function, W₀ and W₁ represent weights of the two fully connected layers, respectively, and M_{c} represents an output channel attention feature map.

In some embodiments, the spatial attention mechanism includes a max pool layer and an average pool layer arranged sequentially and adjacently, and a convolutional layer;
the spatial attention mechanism is expressed as:

$${M}_{s} ( F ) = σ ( {f}^{7 \times 7} ( [ AvgPool ( F ) ; Maxpool ( F ) ] ) ) = σ ( {f}^{7 \times 7} ( [ {F}_{avg}^{s} ; {F}_{max}^{s} ] ) )$$

where F represents an input feature map, σ represents a sigmoid activation function, ƒ^{7×7} represents a 7×7 convolutional operation, and Mₛ represents an output spatial attention feature map.

An embodiment of the disclosure further provides a switchgear fault diagnosis apparatus based on deep learning, which includes a processor and a memory storing a program. The processor, when executing the program stored on the memory, is configured to implement the steps of any of the switchgear fault diagnosis methods described above.

Compared with the related art, the disclosure provides at least the following beneficial effects.

In an embodiment of the disclosure, the provided switchgear fault diagnosis method based on deep learning, by fully utilizing information within raw data, can effectively mine key features of partial discharge patterns, thereby enhancing the model's discrimination capability.

In an embodiment of the disclosure, the provided switchgear fault diagnosis method based on deep learning, through multi-scale feature fusion, enables the model to analyze signal features from different levels and scales, improving adaptability to complex patterns.

In an embodiment of the disclosure, the provided switchgear fault diagnosis method based on deep learning employs an automated feature extraction process of deep learning, reducing reliance on domain expertise and enhancing the system's generalizability and application potential.

In an embodiment of the disclosure, the provided switchgear fault diagnosis method based on deep learning combines global statistical features with locally discriminative features extracted via deep learning, reflecting different dimensional states of partial discharge signals. This can effectively mitigate the impact of noise and anomalous data on recognition results, ensuring reliable fault recognition in complex environments.

In an embodiment of the disclosure, the provided switchgear fault diagnosis method based on deep learning, through the integration of multi-level feature extraction, attention mechanisms, and deep learning model, demonstrates high accuracy in fault detection and type identification. By leveraging precise feature representation and information integration, the model can rapidly identify potential issues and provide accurate fault analysis, thereby significantly improving diagnostic efficiency.

In an embodiment of the disclosure, the provided switchgear fault diagnosis method based on deep learning, due to the generality of its structural design and feature extraction approach, enables the model to adapt to monitoring requirements of different environments. It can be extended to fault diagnosis in diverse application scenarios and environments, possessing strong application potential.

In an embodiment of the disclosure, the switchgear fault diagnosis apparatus based on deep learning can implement the described switchgear fault diagnosis method based on deep learning. Consequently, it possesses at least all the features and advantages of the method, which will not be reiterated here. Additional aspects and advantages of the disclosure will be provided in part in the following description, will become apparent in part from the following description, or may be learned through practice of the disclosure.

### BRIEF DESCRIPTION OF DRAWINGS

FIG. 1 illustrates a flowchart of a switchgear fault diagnosis method based on deep learning according to an embodiment of the disclosure.

FIG. 2 illustrates a schematic diagram of data preprocessing according to an embodiment of the disclosure.

FIG. 3 illustrates a schematic diagram of a ResNet-18 architecture according to an embodiment of the disclosure.

FIG. 4 illustrates a schematic structural diagram of a CBAM according to an embodiment of the disclosure.

FIG. 5 illustrates a schematic structural diagram of a channel attention mechanism according to an embodiment of the disclosure.

FIG. 6 illustrates a schematic structural diagram of a spatial attention mechanism according to an embodiment of the disclosure.

FIG. 7 illustrates a confusion matrix for PRPS-based fault diagnosis according to an embodiment of the disclosure.

FIG. 8 illustrates a confusion matrix for PRPS-based fault pattern classification according to an embodiment of the disclosure.

FIG. 9 illustrates a confusion matrix for PRPD-based fault diagnosis according to an embodiment of the disclosure.

FIG. 10 illustrates a confusion matrix for PRPD-based fault pattern classification according to an embodiment of the disclosure.

### DETAILED DESCRIPTION OF EMBODIMENTS

The technical solutions in embodiments of the disclosure will be described clearly and completely below in conjunction with the accompanying drawings in the embodiments of the disclosure. Apparently, the described embodiments are merely a part of the embodiments of the disclosure, and not all of them. All other embodiments obtained by those of ordinary skill in the art based on the embodiments of the disclosure without creative efforts shall fall within the protection scope of the disclosure.

With reference to the drawings, the embodiments of the disclosure are explained in detail through specific examples and their application scenarios.

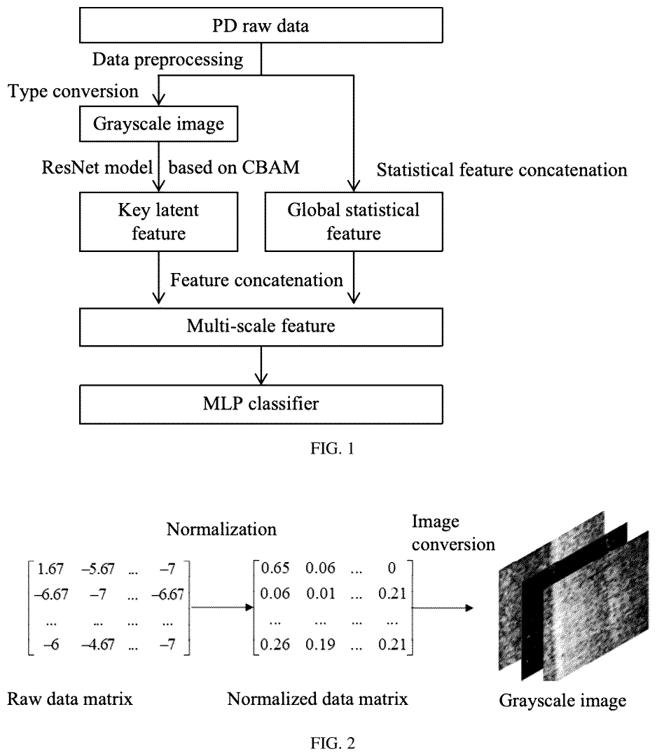

Please refer to FIG. 1, in some embodiments of the disclosure, a switchgear fault diagnosis method based on deep learning is provided. This method utilizes deep neural networks for feature learning, combines channel attention and spatial attention mechanisms to focus on discriminative latent features related to partial discharge patterns, and integrates manually extracted signal statistical features with deep latent features to determine the presence of a fault and, if present, further identify the fault type.

Based on on-site acquired phase resolved pulse sequence (PRPS) data or phase resolved partial discharge (PRPD) data, the following processing steps are performed.
(1) Preprocessing of PD data includes statistical feature extraction and local data transformation. This step extracts global statistical features from the PD data and converts the raw data into a single-channel three-dimensional image matrix, i.e., grayscale image data.
(2) For the converted grayscale images, feature learning is performed using ResNet integrated with an attention mechanism. To address the insufficient feature extraction capability of traditional ResNet networks, the method introduces a CBAM to focus on information relevant to PD patterns. Key local discriminative features representing PD category patterns are obtained through deep feature extraction. The statistical features representing global information of the PD signals and the deeply extracted features representing local information are concatenated and fused to obtain multi-scale features.
(3) A MLP is designed based on the multi-scale features, enabling simultaneous diagnosis of both the presence/absence of a fault and the specific type of the fault.

In some embodiments of the disclosure, the data preprocessing includes the following steps.

### 1) Extraction of Global Statistical Information

Pulse count, as a global feature, offers significant advantages for partial discharge identification. It directly reflects the activity level of partial discharges and provides crucial indications of equipment health status. By monitoring changes in pulse count per unit time, potential faults can be identified in real time and trend analysis can be performed to determine whether discharge activity is progressively intensifying. Furthermore, pulse count calculation is relatively simple and straightforward to understand, facilitating rapid decision-making. It is also less susceptible to the impact of individual anomalous data points, thereby enhancing identification reliability. Comparative analysis of pulse counts across different devices can also aid in rapid identification of abnormal conditions, improving monitoring efficiency.

The mean absolute amplitude of pulses refers to the average value of the absolute amplitudes of all partial discharge pulses within a specific time window. This parameter effectively reflects the overall intensity of partial discharge signals. By calculating the absolute amplitude of each pulse and averaging them, this feature not only provides important basis for fault diagnosis but also exhibits strong anti-interference capability, as the use of absolute values mitigates the impact of negative amplitudes on the results. Additionally, the calculation of mean absolute amplitude is simple and intuitive, facilitating rapid assessment of equipment operational status. Therefore, it holds significant application value in partial discharge feature extraction.

The standard deviation of pulses effectively reflects the volatility of partial discharge signal amplitudes, providing a strong indicator of equipment health status. A higher standard deviation typically indicates greater instability or increased fault risk in the equipment. Moreover, this feature is easily computable and straightforward to interpret in feature analysis, aiding in rapid assessment of equipment operational status. Overall, the standard deviation of pulses serves as an important metric in partial discharge identification and fault diagnosis.

The maximum and minimum values of pulses can help rapidly identify abnormal behaviors and fault conditions in equipment. The magnitude of the maximum value can indicate the presence of serious faults, while the minimum value provides information about signal stability. These two features are simple to compute and facilitate real-time monitoring and quick decision-making, thus holding significant application value in partial discharge identification and fault diagnosis.

### 2) Data-to-Image Transformation

During the monitoring process, PD signals are typically acquired by sensors or detection equipment. These signals may be organized into a two-dimensional data matrix. To effectively convert the data into images, normalization processing must be performed on the data matrix. This operation scales the signal amplitude to the range [0, 1], facilitating subsequent image generation. The normalization includes identifying the minimum and maximum values of the data matrix, followed by application of the following formula:

$$normalized\_data = \frac{PD\_signal - PD\_min}{PD\_max - PD\_min}$$

The normalization enhances image contrast, making signal features more distinct in the resulting images. The normalized data matrix can be converted into grayscale images using image processing libraries. In this step, the normalized data is multiplied by 255 and converted to an unsigned 8-bit integer format (uint8) to adapt to the pixel value range of the grayscale images (0 to 255). The final generated images clearly display the spatial distribution and intensity of partial discharge activity. This process is illustrated in FIG. 2.

In some embodiments of the disclosure, the ResNet model integrated with the CBAM includes the following contents.

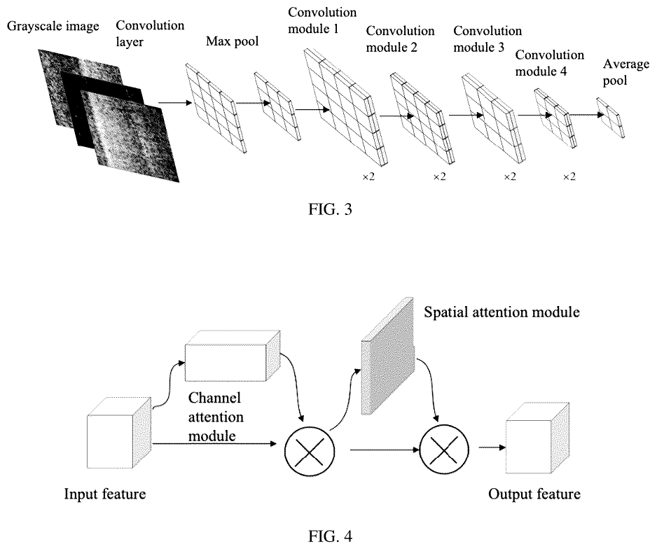

The deep neural network for PD signal pattern feature extraction employs the ResNet18 architecture shown in FIG. 3. The preprocessed grayscale image data is input to the ResNet model. The images pass through multiple residual blocks, each including several convolutional layers that extract features at different hierarchical levels. Through the introduction of skip connections, the network preserves input information during training, ensuring each layer can learn useful features. During feature extraction, batch normalization is applied after convolutional layers to accelerate training and stabilize model performance. By standardizing the output of each layer, it creates more consistent input distributions for subsequent layers, thereby reducing fluctuations during training. Additionally, the ReLU activation function introduces non-linear features, enabling the network to learn more complex patterns. As images propagate through the network layers, the model progressively extracts multi-level information ranging from low-level features (such as edges and textures) to high-level features (such as partial discharge patterns).

To enhance the model's capability for extracting critical features in large-scale data processing, the CBAM is incorporated into the ResNet architecture as shown in FIG. 4. This module primarily includes a channel attention mechanism and a spatial attention mechanism. Through the complementary integration of these two attention mechanisms, the module effectively extracts key information relevant to PD patterns.

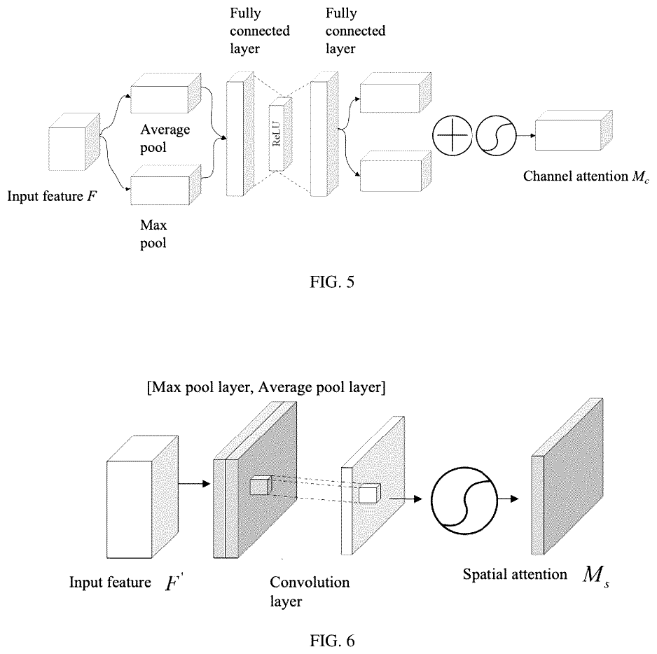

The operational mechanism of the channel attention is illustrated in FIG. 5. The input feature map undergoes parallel average pool (AvgPool) and max pool (MaxPool) layers, which compress the spatial dimensions while maintaining the channel depth, producing two distinct feature maps. These feature maps are then processed through a shared MLP module that first reduces and then expands the channel dimension back to its original size. This dimensional transformation enhances channel feature extraction capability. Subsequently, the outputs are passed through the ReLU activation function and combined using element-wise addition. To convert the features into attention scores, a sigmoid activation function is applied. The attention calculation for this process is represented by the following formula:

$${M}_{c} ( F ) = σ ( MLP ( AvgPool ( F ) ) + MLP ( MaxPool ( F ) ) ) = σ ( {W}_{1} ( {W}_{0} ( {F}_{avg}^{c} ) ) + {W}_{1} ( {W}_{0} ( {F}_{max}^{c} ) ) )$$

where/represents an input feature map, σ represents a sigmoid activation function, W₀ and W₁ represent weights of the two fully connected layers, respectively, and M_{c} represents an output channel attention feature map.

Global average pool and max pool reflect the importance of different channels during the feature extraction process. The model utilizes these descriptors to calculate weights for each channel, enabling the network to focus on the channels most critical for distinguishing partial discharge features. This attention mechanism not only enhances the response to effective signals but also suppresses the influence of redundant or noisy information.

Beyond the channel-level compression and expansion described above, to extract key spatial features of PD signals, the output features from the channel attention mechanism are fed into the spatial attention module shown in FIG. 6. First, the max pool and average pool are applied to compress the feature channels, reflecting the importance of each spatial location in the feature map. Subsequently, the two feature sets are concatenated via the Concat operation and transformed into a single-channel feature map through a convolutional layer. Finally, a sigmoid function converts the feature variables into attention scores. This enables the network to emphasize regions where partial discharge activity is most concentrated, thereby extracting spatial features more effectively. The formula for this process is shown below:

$${M}_{s} ( F ) = σ ( {f}^{7 \times 7} ( [ AvgPool ( F ) ; Maxpool ( F ) ] ) ) = σ ( {f}^{7 \times 7} ( [ {F}_{avg}^{s} ; {F}_{max}^{s} ] ) )$$

where F represents an input feature map, σ represents a sigmoid activation function, ƒ^{7×7} represents a 7×7 convolutional operation, and Mₛ represents an output spatial attention feature map.

Finally, the CBAM is embedded into the basic block of the ResNet network, reducing the model's attention to irrelevant information. This integration enables the model to not only more accurately identify partial discharge patterns but also maintain robustness in complex backgrounds and noisy environments. It reduces the risk of false positives and false negatives during actual monitoring data processing, thereby enhancing overall diagnostic accuracy.

In some embodiments of the disclosure, the MLP classifier based on multi-scale features includes the following contents.

Based on the global statistical features of partial discharge signals and the critical local discriminative features extracted by the deep neural network, a diagnostic classifier using MLP is designed. The classifier primarily includes a shared fully connected layer and two independent fully connected classifiers, used respectively for determining whether a fault exists in the PD signal and identifying the specific fault type.
1) The shared fully connected layer: this layer receives input from the feature extraction part, performs preliminary feature fusion, and extracts more abstract feature representations. The shared fully connected layer can fully utilize the complementary information from both global statistical features and local discriminative features, enhancing the model's learning capability.
2) The fully connected classifier: the fault detection classifier is used to determine whether a fault exists in the PD signal. By providing binary classification results (fault/no fault), it facilitates rapid identification of potential problems. The fault type classifier is used to further categorize fault types, such as internal discharge, surface discharge, and corona discharge. This layer provides multi-level fault classification, contributing to more precise localization and diagnosis of specific fault causes.

Through this multi-level classification design, the model not only improves the accuracy of fault detection but also enables in-depth analysis of fault types. The shared fully connected layer effectively integrates different features, enhancing the model's ability to recognize complex patterns and ultimately increasing the overall diagnostic accuracy. The flexibility and hierarchical nature of this architecture enable the model to make rapid and accurate judgments when faced with diverse PD signals, thereby providing more reliable support for power equipment maintenance.

The disclosure combines global statistical features with locally discriminative features extracted through deep learning. Through multi-level information fusion, it captures multi-dimensional information of the signals, helping the model more comprehensively understand partial discharge patterns and enhancing the model's feature representation capability. The adopted CBAM effectively strengthens the extraction of key information through the combination of channel attention and spatial attention mechanisms. The channel attention mechanism weights features according to the importance of different channels, while the spatial attention mechanism emphasizes important spatial locations in the feature maps. This mechanism ensures the model focuses on regions where partial discharge activity is most concentrated. The design of the shared fully connected layer with independent classifiers provides higher flexibility for both fault detection and type identification. The shared fully connected layer integrates different features to enhance learning capability, while the independent classifiers separately handle fault existence determination and type identification, improving the model's performance in dealing with complex patterns.

The following are two practical application examples of the disclosure and their results.

### Example 1

Based on PRPS data acquired through ultrasonic sensors, deep feature extraction and pattern recognition tasks were performed. The model parameter settings are shown in Table 1.

TABLE 1
model parameter settings for PRPS data experiment

| Training Set | Test Set | Iterations | Learning Rate | Image Dimensions |
|---|---|---|---|---|
| 1380 | 345 | 30 | 1e−5 | 50 × 60 |

The MLP classifier designed based on global features and deep critical features can effectively perform fault diagnosis and pattern classification on equipment data of actual substation switchgear. Specifically, PRPS data monitoring was conducted on three different switchgears in the field. These three switchgears were known to exhibit different partial discharge patterns, categorized as: no partial discharge, low-intensity partial discharge, and high-intensity partial discharge. Feature extraction and fault diagnosis were performed on the PRPS data from the three different switchgears. The input data was grayscale images obtained through normalization processing and image transformation of PRPS data. After deep feature extraction through the deep neural network, the discriminative latent features were fused with global statistical features of the PRPS data and then input to the MLP classifier. The classifier effectively performed fault diagnosis and pattern recognition. The recognition results are shown in Table 2 below.

TABLE 2
pattern recognition accuracy for PRPS data experiment

| Classification Criteria | Fault Diagnosis | Fault Type Diagnosis |
|---|---|---|
| Accuracy | 99.71% | 98.84% |

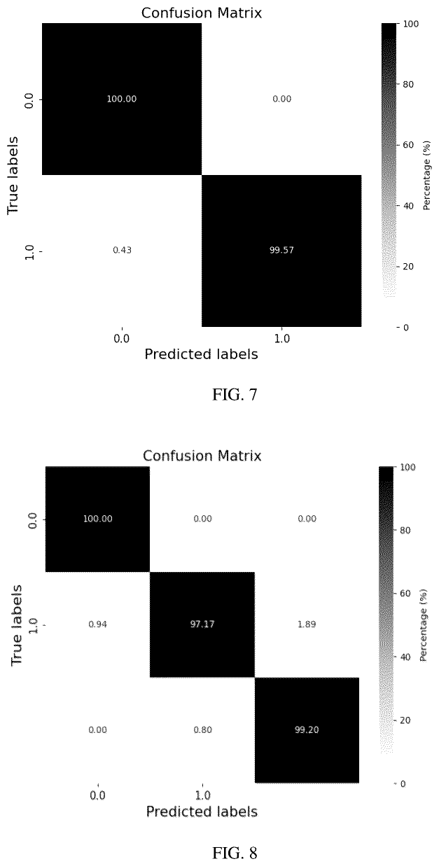

Specifically, the fault diagnosis accuracy reached 99.71%, and the fault classification accuracy reached 98.84%. The confusion matrix for fault diagnosis is shown in FIG. 7, and the confusion matrix for fault pattern classification is shown in FIG. 8. In these matrices, 0 represents no fault (no partial discharge), 1 indicates partial discharge occurrence with low intensity, and 2 indicates partial discharge occurrence with high intensity. The partial discharge pattern recognition algorithm proposed in the disclosure can effectively classify partial discharge in monitored PRPS data with high classification accuracy.

### Example 2

Based on PRPD data acquired through ultrasonic sensors, deep feature extraction and pattern recognition tasks were performed. The model parameter settings are shown in Table 3.

TABLE 3
model parameter settings for PRPD data experiment

| Training Set | Test Set | Iterations | Learning Rate | Image Dimensions |
|---|---|---|---|---|
| 1374 | 344 | 30 | 1e−5 | 60 × 80 |

The MLP classifier designed based on global features and deep critical features can effectively perform fault diagnosis and pattern classification on equipment data of actual substation switchgear. Specifically, PRPD data monitoring was conducted on three different switchgears in the field. These three switchgears were known to exhibit different partial discharge patterns, categorized as: no partial discharge, low-intensity partial discharge, and high-intensity partial discharge. Feature extraction and fault diagnosis were performed on the PRPD data from the three different switchgears. The input data was grayscale images obtained through normalization processing and image transformation of PRPD data. After deep feature extraction through the deep neural network, the discriminative latent features were fused with global statistical features of the PRPD data and then input to the MLP classifier. The classifier effectively performed fault diagnosis and pattern recognition. The recognition results are shown in Table 4.

TABLE 4
pattern recognition accuracy for PRPD data experiment

| Classification Task | Fault Diagnosis | Fault Type Identification |
|---|---|---|
| Accuracy | 99.71% | 98.55% |

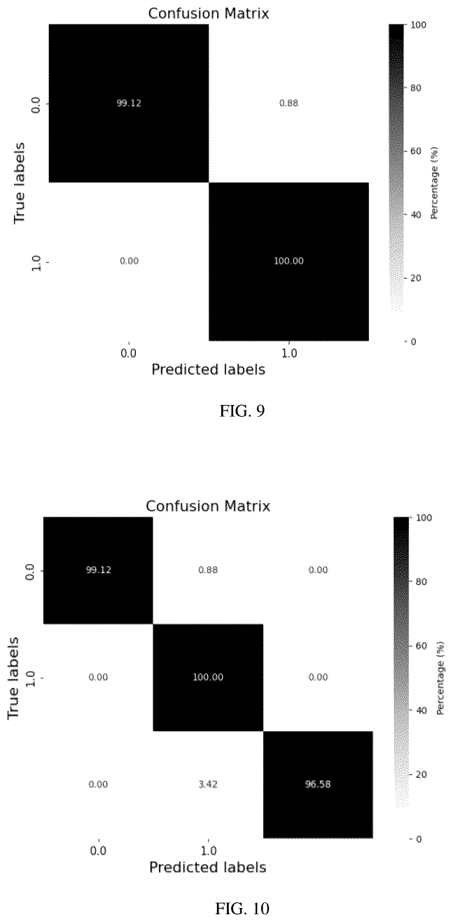

Specifically, the fault diagnosis accuracy reached 99.71%, and the fault classification accuracy reached 98.55%. The confusion matrix for fault diagnosis is shown in FIG. 9, and the confusion matrix for fault pattern classification is shown in FIG. 10. In these matrices, 0 represents no fault (no partial discharge), 1 indicates partial discharge occurrence with low intensity, and 2 indicates partial discharge occurrence with high intensity. The partial discharge pattern recognition algorithm proposed in the disclosure can effectively classify partial discharge in monitored PRPD data with high classification accuracy.

Portions of the disclosure not described in detail herein may be implemented with reference to the prior art or technologies well-known to persons skilled in the art.

While the embodiments of the disclosure have been described above with reference to the accompanying drawings, the disclosure is not limited to the specific implementations described herein. These implementations are merely illustrative rather than restrictive. Based on the teachings of the disclosure, those of ordinary skill in the art may develop numerous alternative forms without departing from the spirit of the disclosure or the scope of protection defined by the claims. All such variations shall fall within the protection scope of the disclosure.

What is claimed is:

1. A switchgear fault diagnosis method based on deep learning, comprising:
S1, acquiring partial discharge (PD) data;
S2, preprocessing the acquired PD data, and the preprocessing comprising:
performing global statistical feature extraction on the PD data to obtain global statistical features; and
performing data type conversion on the PD data to obtain grayscale images;
S3, processing the grayscale images using a residual network (ResNet) model integrated with a convolutional block attention module (CBAM) to extract key latent features as key local discriminative features;
S4, concatenating the global statistical features and the key local discriminative features to obtain multi-scale features; and
S5, classifying the multi-scale features using a multilayer perceptron (MLP) classifier to obtain a switchgear fault diagnosis result;
wherein the global statistical features comprise a number of pulses, a mean absolute amplitude of the pulses, a standard deviation of the pulses, and maximum and minimum values of the pulses;
wherein the PD data comprises phase resolved pulse sequence (PRPS) data or phase resolved partial discharge (PRPD) data; and
wherein the MLP classifier is a multilayer perceptron designed based on the multi-scale features, and the switchgear fault diagnosis result comprises presence or absence of a fault and a type of the fault.

2. The switchgear fault diagnosis method as claimed in claim 1, wherein the CBAM comprises a channel attention mechanism and a spatial attention mechanism, and a mutual combination of the channel attention mechanism and the spatial attention mechanism effectively extracts the key latent features related to PD patterns.

3. The switchgear fault diagnosis method as claimed in claim 1, wherein the performing data type conversion on the PD data to obtain grayscale images in S2 comprises:
arranging the PD data into a two-dimensional data matrix;
performing normalization on the two-dimensional data matrix to obtain normalized data; and
multiplying the normalized data by 255 to obtain multiplied data, and converting the multiplied data into an integer format to adapt to a pixel value range of the grayscale images from 0 to 255, thereby obtaining the grayscale images that clearly display spatial distribution and intensity of a partial discharge activity.

4. The switchgear fault diagnosis method as claimed in claim 1, wherein the CBAM is embedded within a basic block of the ResNet model.

5. The switchgear fault diagnosis method as claimed in claim 2, wherein the channel attention mechanism comprises an average pool layer and a max pool layer arranged in parallel, a first fully connected layer, a ReLU module, and a second fully connected layer;
wherein a formula of the channel attention mechanism is:
$${M}_{c} ( F ) = σ ( MLP ( AvgPool ( F ) ) + MLP ( MaxPool ( F ) ) ) = σ ( {W}_{1} ( {W}_{0} ( {F}_{avg}^{c} ) ) + {W}_{1} ( {W}_{0} ( {F}_{max}^{c} ) ) )$$
where F represents an input feature map, σ represents a sigmoid activation function, W₀ and W₁ represent weights of the first and second fully connected layers, respectively, and M_{c} represents an output channel attention feature map.

6. The switchgear fault diagnosis method as claimed in claim 2, wherein the spatial attention mechanism comprises a max pool layer and an average pool layer arranged sequentially and adjacently, and a convolutional layer;
wherein a formula of the spatial attention mechanism is:
$${M}_{s} ( F ) = σ ( {f}^{7 \times 7} ( [ AvgPool ( F ) ; Maxpool ( F ) ] ) ) = σ ( {f}^{7 \times 7} ( [ {F}_{avg}^{s} ; {F}_{max}^{s} ] ) )$$
where F represents an input feature map, σ represents a sigmoid activation function, ƒ^{7×7} represents a 7×7 convolutional operation, and Mₛ represents an output spatial attention feature map.

7. A switchgear fault diagnosis apparatus based on deep learning, comprising a processor and a memory storing a program, wherein the processor, when executing the program stored on the memory, is configured to implement the switchgear fault diagnosis method as claimed in claim 1.
